(19) United States
(12) Patent Application Publication
(10) Pub. No.: US 2008/0273141 A1
(43) Pub. Date: Nov. 6, 2008

(54) Light-Emitting Diode Package

(76) Inventors: Ying-Hao Hsu, Tainan Science Based Industrial Park (TW); Wei-Ming Pai, Tainan Science Based Industrial Park (TW)

Correspondence Address: TROP PRUNER & HU, PC, 1616 S. VOSS ROAD, SUITE 750, HOUSTON, TX, 77057-2631, US

(21) Appl. No.: 12/109,762

(22) Filed: Apr. 25, 2008

(30) Foreign Application Priority Data
Apr. 26, 2007 (TW) 96114740

(51) Int. Cl. G02F 1/13357; F21V 8/00; H01L 33/00

(52) U.S. Cl. 349/62; 257/89; 362/231; 257/E33.058

(57) ABSTRACT

A light-emitting diode (LED) package includes a holder. In one implementation, first and second light-emitting chips associated with different wavelengths but same color are disposed on the holder. In another implementation, first and second light-emitting chips associated with different brightnesses but same chroma are disposed on the holder. In yet another implementation, a plurality of first, second, and third color light-emitting chips are disposed symmetrically about a center of the holder.

### CROSS-REFERENCE TO RELATED APPLICATION

This claims priority under 35 U.S.C. § 119 of Taiwan Application No. 96114740, filed Apr. 26, 2007, which is hereby incorporated by reference.

### TECHNICAL FIELD

The present invention relates to a light-emitting diode (LED) package, and more particularly to an LED package and applications thereof.

### BACKGROUND

Recently, due to improvement of the light-emitting efficiency of the light-emitting diodes (LED), LEDs (especially white LEDs) have gradually replaced fluorescent lamps and incandescent lamps in some applications, such as in scanner light sources, backlight sources, or frontlight sources of a liquid crystal display (LCD) device, light sources for illumination of instrument panels of automobiles, traffic lights, and other illuminating devices.

Frequently, LEDs are semiconductor devices that include materials selected from Group III-V elements such as GaP, GaAs, and GaN. An LED converts electrical power into light by applying an electrical current through one of the foregoing semiconductor materials to release excessive energy in the form of light.

LEDs are cold light sources that emit light rays without heating or discharging. Therefore, the lifespan of LEDs can extend up to 100,000 hours. Also, idling time of LEDs is not required. Furthermore, LEDs have relatively quick response times (on the order of about 10⁻⁹ seconds), and are relatively small in size, consume low power, are associated with low pollution, have high reliability, and are readily mass producible.

White LEDs currently available in the market may generate white light by using a blue light-emitting chip to excite yellow phosphor, or by using red, green, and blue LED chips to emit red, green, and blue lights, which are mixed into white light having three wavelengths. The latter white LEDs are formed by mounting the red, green, and blue LED chips on the same holder. However, since the epitaxy process of LEDs is relatively complex, photoelectric characteristics of LED chips fabricated on the same wafer cannot maintain desired consistency, such that LED chips may be associated with varying specifications (e.g., wavelengths, brightness).

FIGS. 1A and 1B are charts depicting production throughput distributions of a green LED chip. FIG. 1A illustrates the relationship of production throughput proportions with wavelengths of the green LED chip, and FIG. 1B illustrates the relationship of production throughput proportions with brightness of the green LED chip. “Production throughput proportion” represents a manufacturing yield of a green LED chip that meets (or satisfies) a target specification (in terms of wavelength and/or brightness). As shown in FIGS. 1A and 1B, under the specification of a specific wavelength such as 525-530 nm or a specific brightness such as 550-560 mcd, the throughput of the green LED chips is a low proportion of the overall throughput, and thus the green LED chips under this specification are quite expensive. The red LED chips and the blue light-emitting chips have the same problem as well.

Therefore, in order to achieve a good display quality, the displays must adopt the LED chips with a small specification range as light sources of the backlight modules, thus leading to a high manufacturing cost of the displays.

FIG. 2 schematically depicts a package 10 of a conventional white LED. To effectively shorten light mixing distance, the conventional white LED package 10 includes the red, green, and blue light-emitting chips 13, 14, and 12 that are arranged generally in a triangular configuration, and packaged on the same holder 11. However, this arrangement of the light-emitting chips will lead to an asymmetrical light field of the white LED package 10.

FIGS. 3A, 3B, and 3C illustrate light fields of red, green, and blue light-emitting chips, respectively, arranged as in FIG. 2. As shown, the backlight module using the white LED package of FIG. 2 has a color shift problem across different viewing angles. For example, as depicted in FIG. 3B, the axis of the light having the maximum intensity of the green light field (represented as 22) is deviated to the right side of the central axis 20, and the axes of the light having the maximum intensity of the red and blue light fields (24 and 26, respectively, in FIGS. 3A and 3C) are deviated to the left side of the central axis 20. After the white chroma when viewing from the front side is defined, the color shifts to the green tone when viewing from the right, and shifts to the purple tone (mixture of red and blue) when viewing from the left. The color shift problem when viewing from different angles adversely influences the display quality of an LCD device or other type of device that uses the light source of FIG. 2.

### BRIEF DESCRIPTION OF THE DRAWINGS

FIG. 1A is a graph that illustrates the relationship of production throughput proportions with wavelengths of a green LED (light-emitting diode) chip.

FIG. 1B is a graph that illustrates the relationship of production throughput proportions with brightness of the green LED chip.

FIG. 2 is a schematic view of a package of a conventional white LED.

FIGS. 3A, 3B, and 3C are charts illustrating light fields of red, green, and blue light-emitting chips, respectively.

FIG. 4 is a schematic view of an LED package according to a first embodiment of the present invention.

FIG. 5A is a chromaticity diagram.

FIG. 5B is a chart illustrating the relationship of production throughput proportions with wavelength ranges of first and the second light-emitting chips in the LED package of FIG. 4.

FIG. 6 is a schematic view of an LCD device using the LED package.

FIG. 7 is a chart illustrating the relationship of production throughput proportions with brightness of the first and the second light-emitting chips according to a second embodiment of the present invention.

FIG. 8 is a schematic view of an LED package according to the second embodiment.

FIG. 9 is a schematic view of an LED package according to a third embodiment of the present invention.

FIGS. 10A, 10B, and 10C are charts respectively illustrating light fields of red light, green light, and blue light of the LED package according to an embodiment.

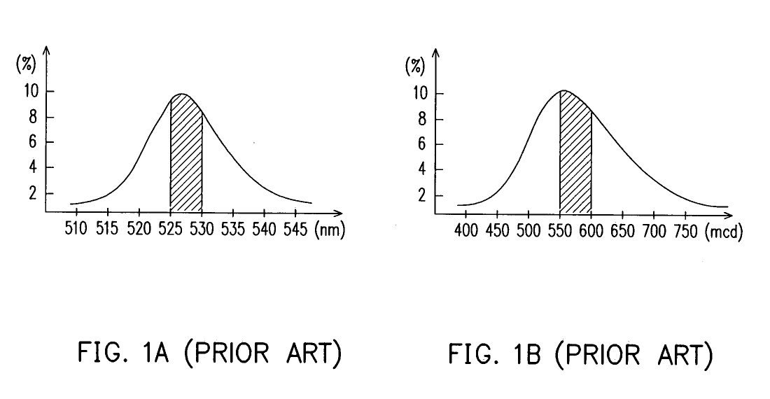

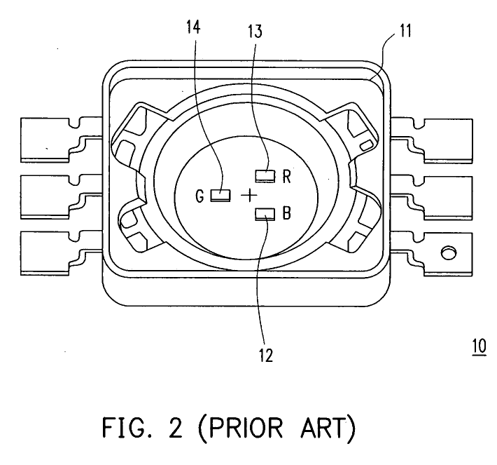

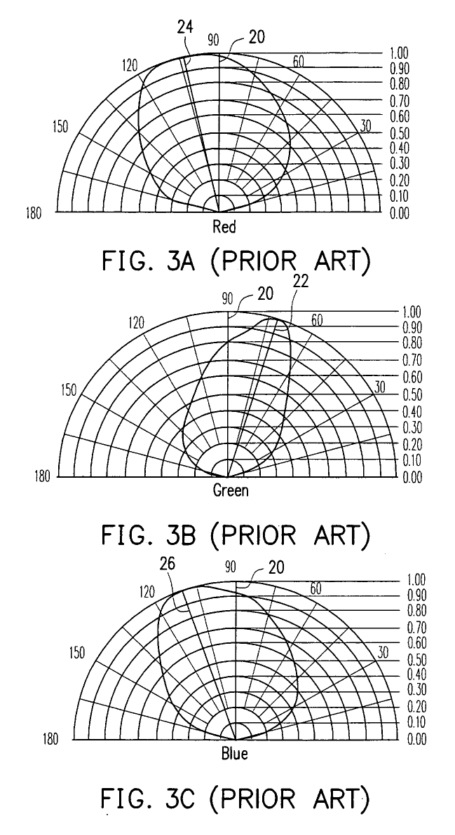

### DETAILED DESCRIPTION

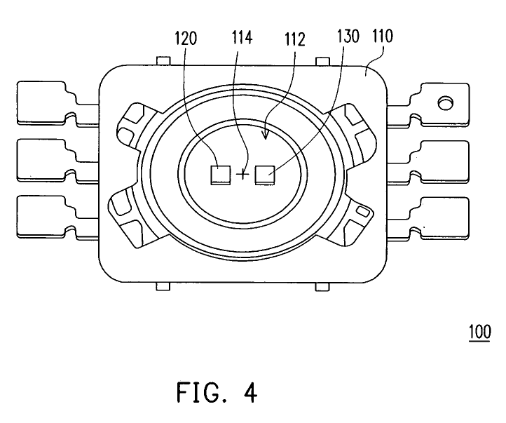

FIG. 4 illustrates an LED (light-emitting diode) package 100 according to a first embodiment of the present invention. The LED package 100 includes a holder 110, and a first light-emitting chip 120 and a second light-emitting chip 130 of the same color. A “holder” refers to a support structure, containment structure, or any other structure on which light-emitting chips can be mounted. A “light-emitting chip” refers to an LED, or alternatively, to an LED in combination with associated circuitry. In one embodiment, the holder 110 is a package substrate, and the color of each of the first light-emitting chip 120 and the second light-emitting chip 130 may be one of red, green, and blue. In other implementations, light-emitting chips of other colors can be used.

The holder 110 has a recess 112, and the first light-emitting chip 120 and the second light-emitting chip 130 are disposed in the recess 112, such that the first light-emitting chip 120 and the second light-emitting chip 130 are packaged on the holder 110.

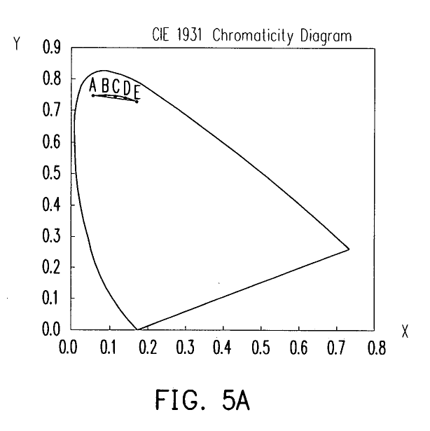

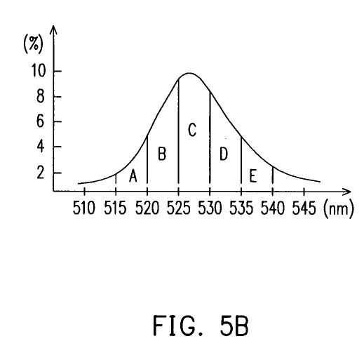

Under the same brightness specification, the first light-emitting chip 120 and the second light-emitting chip 130 have different wavelength ranges. FIG. 5A is a chromaticity chart, and FIG. 5B is a chart illustrating the relationship of throughput proportions to wavelength ranges of the first and the second light-emitting chips. Referring to FIGS. 5A and 5B, under the same brightness specification (of for example a green light), the chroma of the first light-emitting chip 120 is B in FIG. 5A, which corresponds to the wavelength range of region B (520-525 nm) in FIG. 5B. Moreover, the chroma of the second light-emitting chip 130 is D in FIG. 5A, which corresponds to the wavelength range of region D (530-535 nm) in FIG. 5B. In other words, the wavelength of the first light-emitting chip 120 is shorter than the wavelength of the second light-emitting chip 130, but both produce light of the same color.

When the LED package 100 is driven by a voltage, the light-emitting chips 120 and 130 both emit light. The light of the first light-emitting chip 120 is mixed with the second light-emitting chip 130. Due to this mixing, the chroma exhibited by the LED package 100 is similar to the chroma of the LED package using two light-emitting chips having the wavelength range of region C (525-530 nm) in FIG. 5B, i.e., similar to the chroma of C in FIG. 5A.

According to the above, an LED package can be provided with light-emitting chips having a long wavelength and a short wavelength, but of the same color, such that the chroma exhibited by the LED package 100 can meet the specification of a user. In another example, the wavelength range of the first light-emitting chip 120 may be region A (515-520 nm) in FIG. 5B, i.e. the chroma A in FIG. 5A. Moreover, the wavelength range of the second light-emitting chip 130 may be region E (535-540 nm) in FIG. 5B, i.e. the chroma E in FIG. 5A. Meanwhile, the chroma exhibited by the LED package 100 is similar to the chroma of the light-emitting chip having the wavelength range of region C (525-530 nm), i.e., the chroma C in FIG. 5A.

In this manner, to achieve a uniform chroma specification for an LED package, different light-emitting chips of varying specifications (e.g., wavelengths) can be selected for inclusion in the LED package. Since different light-emitting chips of different specifications can be used, manufacturing costs can be reduced. Note that light-emitting chips are manufactured on wafers, with multiple light-emitting chips formed on each wafer. As noted above, it may be difficult to manufacture light-emitting chips having uniform consistency in terms of wavelength and/or brightness. By being able to select different combinations of light-emitting chips to include in an LED package to achieve a target chroma, manufacturing efficiency can be enhanced. This means that a larger number of light-emitting chips on a wafer can be used, which enhances yield and reduces manufacturing cost.

To achieve a more uniform overall chroma performance of the LED package 100, the holder 110 has a center 114, with the first light-emitting chip 120 and the second light-emitting chip 130 symmetrically arranged on two sides of the center 114.

Moreover, although only the green light-emitting chip is taken as an example for illustrating the above LED package 100, note that similar arrangements can be used with red or blue light-emitting chips in the LED package. Furthermore, each of red, green, and blue light-emitting chips may be included in one LED package, so as to form a white LED package by mixing light from the red, green, and blue light-emitting chips.

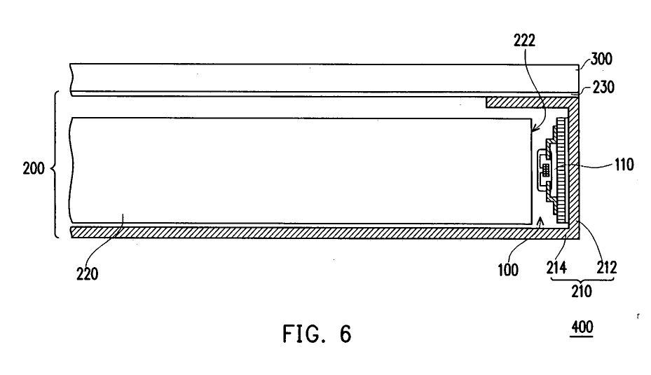

FIG. 6 is a schematic view of an LCD device 400 using the LED package 100 according to an embodiment. The LCD device includes a backlight module 200 that includes LED package 100 as a light source of the backlight module 200. A plurality of the LED packages 100 are first arranged on a bar-shaped substrate to form a light bar. Alternatively, the plurality of light-emitting chips having different colors can be directly packaged on the bar-shaped holder 110.

Next, the holder 110 is disposed in a frame 210, where the position of the holder 110 in the frame 210 is determined by the type of the backlight module 200.

If the backlight module 200 is a side-type backlight module, the holder 110 is disposed on a side wall 212 of the frame 210. Moreover, a light guide plate 220 is disposed in the frame 210, and the LED package 100 serving as the light source is located beside a light incident surface 222 of the light guide plate 220, so that the light guide plate 220 guides the light emitted by the LED package 100 to a correct light output direction.

If the backlight module is a direct-type backlight module, the LED package 100 is disposed at the bottom 214 of the frame 210. In other words, the LED package 100 is located between the frame 210 and the diffusion plate disposed on the frame 210.

In addition, an LCD panel 300 is placed on the backlight module 200 to form the LCD device 400. To achieve a better display quality of the LCD device 400, the backlight module 200 further includes an optical film 230 disposed between the frame 210 and the LCD panel 300, and the optical film 230 may be a diffusion film, a brightness enhancement film, or a prism film.

By using the LED package of the first embodiment in a backlight module, the backlight module can achieve uniform chroma of the light source, so that the LCD device has good display quality.

An LED package in the second embodiment is similar to the LED package in the first embodiment, and the same or similar elements are indicated by the same or similar element numerals. Different from the first embodiment, the first light-emitting chip and the second light-emitting chip in the second embodiment have the same chroma but different brightness.

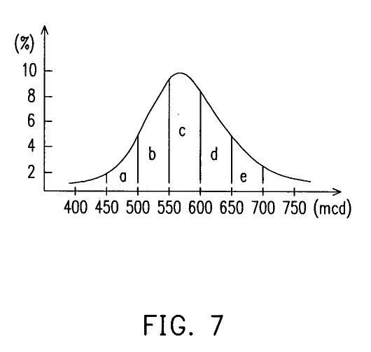

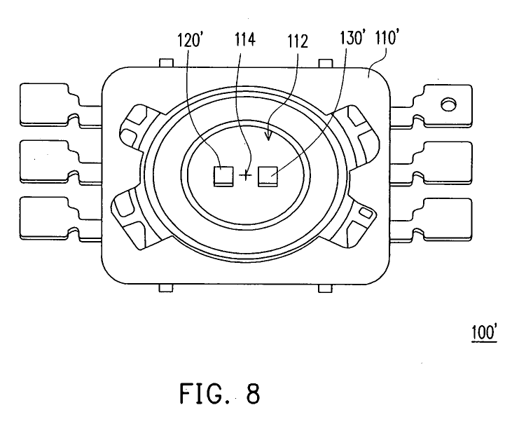

FIG. 7 is a chart illustrating the relationship between throughput proportions and the brightness of the first and the second light-emitting chips for the second embodiment. FIG. 8 is a schematic view of an LED package according to the second embodiment. Referring to FIGS. 7 and 8, in an LED package 100′ of this second embodiment which is similar to the first embodiment, a first light-emitting chip 120′ having a range of brightness in region b (500-550 mcd) and a second light-emitting chip 130′ having a range of brightness in region d (600-650 mcd) are both disposed on a holder 110′. The general arrangement of the LED package 100′ is the same as the LED package 100 in the first embodiment.

The second light-emitting chip 130′ having a low brightness and the first light-emitting chip 120′ having a high brightness are disposed on the same holder 110′, and the light of the first light-emitting chip 120′ is mixed with the light of the second light-emitting chip 130′. After the light mixing, the brightness performance of the LED package 100′ is the same as that of the LED package using two light-emitting chips having a range of brightness in region c (550-600 mcd).

Likewise, a first light-emitting chip 120′ having a range of brightness in region a (450-500 mcd) and a second light-emitting chip 130′ having a range of brightness in region e (650-700 mcd) may also be disposed on a holder 110′, so as to achieve the brightness performance of the LED package using two light-emitting chips having a range of brightness in region c (550-600 mcd).

In this manner, the LED package 100′ uses two light-emitting chips having a high and a low brightness to achieve the desired brightness performance, and thus more light-emitting chips can be selected from the same wafer, thereby reducing manufacturing cost. Moreover, the backlight module (not shown) using the LED package 100′ still has a brightness consistency, and the LCD device incorporating the backlight module can achieve good display quality.

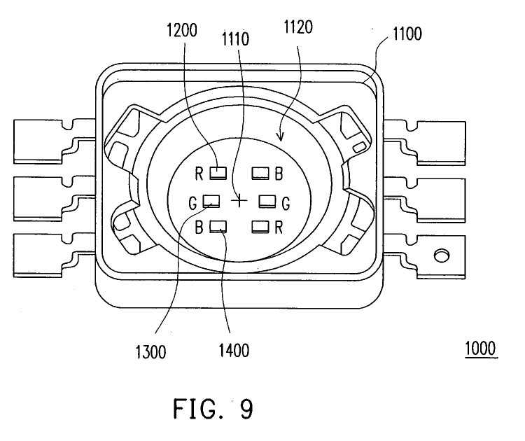

FIG. 9 is a schematic view of an LED package 1000 according to a third embodiment of the present invention. The LED package 1000 includes a holder 1100, a plurality of first color light-emitting chips 1200, a plurality of second color light-emitting chips 1300, and a plurality of third color light-emitting chips 1400. The holder 1100 of this embodiment is a package substrate, and has a center 1110. The center 1110 may be a symmetrical central point or a symmetrical central line about which the light-emitting chips are arranged symmetrically. Moreover, for the convenience of packaging, the holder 1100 further has a recess 1120, and the center 1110 is in the recess 1120.

The first color light-emitting chips 1200, the second color light-emitting chips 1300, and the third color light-emitting chips 1400 are disposed in the holder 1100, and symmetrically arranged in the recess 1120 of the holder 1100 about the center 1110. Moreover, the first, the second, and the third color of the first color light-emitting chips 1200, the second color light-emitting chips 1300, and the third color light-emitting chips 1400 are red, green, and blue, respectively. For example, the first color light-emitting chips 1200 are red light-emitting chips, the second color light-emitting chips 1300 are green light-emitting chips, and the third color light-emitting chips 1400 are blue light-emitting chips.

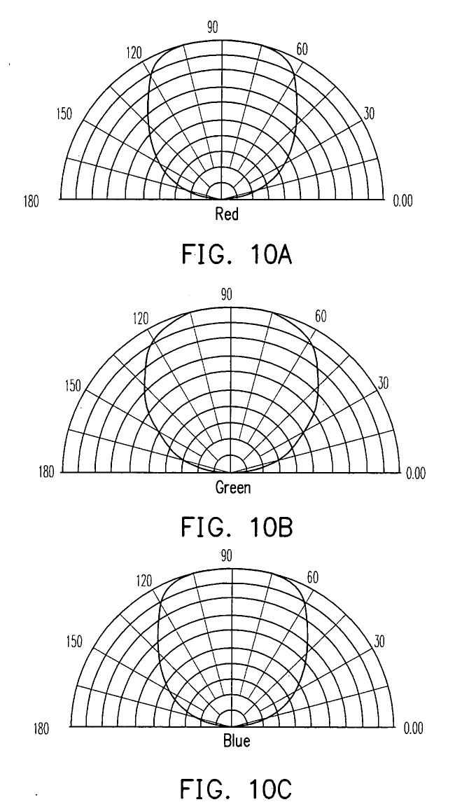

FIGS. 10A, 10B, and 10C are charts respectively illustrating light fields of a red light, a green light, and a blue light of the LED package 1000 according to the third embodiment. Referring to FIGS. 10A, 10B, and 10C together, the first color light-emitting chips 1200, the second color light-emitting chips 1300, and the third color light-emitting chips 1400 are symmetrically disposed in the holder 1100. Therefore, the red light, the green light, and the blue light of the LED package 1000 in this embodiment all have symmetrical light fields. Moreover, the first color light-emitting chips 1200, the second color light-emitting chips 1300, and the third color light-emitting chips 1400 may mix the light uniformly, so that the LED package 1000 has a uniform white light.

Although two first color light-emitting chips 1200, two second color light-emitting chips 1300, and two third color light-emitting chips 1400 are illustrated as an example in FIG. 9, an alternative embodiment can include more than two light-emitting chips for each color.

Moreover, when the LED package 1000 in this embodiment is applied in a backlight module, the backlight module also has a symmetrical light field. Therefore, the user will not be bothered by the color shift problem when viewing the backlight module from the front, the right, or the left (at different angles).

If the backlight module is applied in an LCD device, the symmetrical light field provided for the LCD panel by the backlight module may effectively solve the color shift problem of the LCD device when viewing from different angles, thereby improving the display quality of the LCD device.

It should be noted that, under the consideration of the same luminous flux, the area of each first color light-emitting chip 1200, second color light-emitting chip 1300, and third color light-emitting chip 1400 may be reduced in this embodiment. For example, in a conventional LED package, the light-emitting chip having an area of 20*20 mil² (1 mil is 1/1000 inch) is used. In the LED package 1000 of this embodiment, the area of the light-emitting chip may be reduced to 14 mil*14 mil, and the area of the LED package 1000 is a half of the conventional LED package. Since the number of chips of the same color is two in this embodiment, the total light-emitting area is equivalent to that of the conventional chip and the same luminous flux is maintained.

One or more of the following benefits can be provided by some embodiments. The light-emitting chips respectively having a long and a short wavelength but with the same color is used to achieve the specifications required by the user. Therefore, the chroma ranges of the light-emitting chips on the same wafer that can be selected are greater, such that the numbers of the light-emitting chips on the same wafer that can be selected is greater too.

The light-emitting chips having a high and a low brightness but with the same chroma are co-located to achieve the specifications required by a user. Therefore, the chroma ranges of the light-emitting chips on the same wafer that can be selected greater, such that the numbers of the light-emitting chips on the same wafer that can be selected is greater too.

A plurality of light-emitting chips having a variety of colors are symmetrically disposed on the holder to achieve the symmetrical light field, thus solving the color shift problem of the LCD apparatus when viewing from different angles. Therefore, the liquid crystal display has a better display quality than the conventional art.

While the invention has been disclosed with respect to a limited number of embodiments, those skilled in the art will appreciate numerous modifications and variations therefrom. It is intended that the appended claims cover such modifications and variations as fall within the true spirit and scope of the invention.

What is claimed is:

1. A light-emitting diode (LED) package, comprising:
a holder; and
first and second light-emitting chips, disposed on the holder, and associated with different wavelength ranges but a same color.

2. The LED package as claimed in claim 1, wherein the holder has a center, and the first and the second light-emitting chips are symmetrically arranged on the holder about the center.

3. The LED package as claimed in claim 1, wherein the holder has a recess, and the first and the second light-emitting chips are disposed in the recess.

4. The LED package as claimed in claim 1, wherein the holder is a package substrate.

5. A backlight module, comprising:
a frame;
a light source, disposed in the frame, comprising:
a holder, disposed on the frame; and
first and second light-emitting chips, disposed on the holder, and associated with different wavelength ranges but a same color.

6. The backlight module as claimed in claim 5, wherein the holder has a center, and the first and the second light-emitting chips are symmetrically arranged on the holder about the center.

7. The backlight module as claimed in claim 5, further comprising a light guide plate disposed in the frame, wherein the light guide plate has a light incident side, and the light source is located adjacent the light incident side.

8. The backlight module as claimed in claim 5, further comprising a diffusion plate disposed on the frame, wherein the light source is located between the diffusion plate and the frame.

9. The backlight module as claimed in claim 5, further comprising an optical film disposed on the frame.

10. The backlight module as claimed in claim 9, wherein the optical film comprises a diffusion film, a brightness enhancement film, or a prism film.

11. A liquid crystal display (LCD) device, comprising:
the backlight module according to claim 5; and
an LCD panel disposed on the backlight module.

12. A light-emitting diode (LED) package, comprising:
a holder; and
first and second light-emitting chips, disposed on the holder, and associated with different brightnesses but a same chroma.

13. The LED package as claimed in claim 12, wherein the holder has a center, and the first and the second light-emitting chips are symmetrically arranged on the holder about the center.

14. The LED package as claimed in claim 12, wherein the holder has a recess, and the first and the second light-emitting chips are disposed in the recess.

15. A backlight module, comprising:
a frame;
a light source, disposed in the frame, comprising:
a holder, disposed on the frame; and
first and second light-emitting chips, disposed on the holder, and associated with different brightnesses but a same chroma.

16. The backlight module as claimed in claim 15, further comprising a light guide plate disposed in the frame, wherein the light guide plate has a light incident side, and the light source is located adjacent the light incident side.

17. The backlight module as claimed in claim 15, further comprising a diffusion plate disposed on the frame, wherein the light source is located between the diffusion plate and the frame.

18. The backlight module as claimed in claim 15, further comprising an optical film disposed on the frame.

19. A liquid crystal display (LCD) device, comprising:
the backlight module according to claim 16; and
an LCD panel disposed on the backlight module.

20. A light-emitting diode (LED) package, comprising:
a holder having a center; and
a plurality of first, second, and third color light-emitting chips, symmetrically arranged about the center.

21. The LED package as claimed in claim 20, wherein the holder has a recess, and the center is in the recess, and the first, the second, and the third color chips are all disposed in the recess.

22. The LED package as claimed in claim 20, wherein the first, the second, and the third colors are red, green, and blue, respectively.

23. A backlight module, comprising:
a frame;
a light source, disposed in the frame, comprising:
a holder, disposed on the frame, and having a center; and
first color light-emitting chips symmetrically arranged about the center;
second color light-emitting chips symmetrically arranged about the center; and
third color light-emitting chips symmetrically arranged about the center.

24. A liquid crystal display (LCD) device, comprising:
a backlight module according to claim 24; and
an LCD panel disposed on the backlight module.
